(19) United States
(12) Patent Application Publication
(10) Pub. No.: US 2023/0333148 A1
(43) Pub. Date: Oct. 19, 2023

(54) DEVICE AND METHOD FOR WAVEFORM SEARCHING BY EXAMPLE

(71) Applicant: Tektronix, Inc., Beaverton, OR (US)

(72) Inventors: Lance H. Forsberg, Beaverton, OR (US); Keith D. Rule, Beaverton, OR (US); David N. Wyban, Portland, OR (US)

(73) Assignee: Tektronix, Inc., Beaverton, OR (US)

(21) Appl. No.: 18/135,066

(22) Filed: Apr. 14, 2023

Related U.S. Application Data
(60) Provisional application No. 63/332,673, filed on Apr. 19, 2022.

(51) Int. Cl. G01R 23/00; G01R 13/02; G01R 1/04; G01R 1/02

(52) U.S. Cl. CPC G01R 23/005; G01R 13/0227; G01R 13/0272; G01R 1/0416; G01R 1/025

(57) ABSTRACT

A test and measurement instrument includes an input for accepting an input signal from a Device Under Test (DUT), acquisition memory for storing a sampled waveform derived from the input signal, an output display, and one or more processors configured to accept a portion of the sampled waveform as a search portion, search the sampled waveform for portions similar to the search portion, and visually indicate, on the output display, portions of the sampled waveform that are similar to the search portion as matched portions. Methods of operation and description of storage media, the operation of which performs the above operations, are also described.

### CROSS-REFERENCE TO RELATED APPLICATIONS

This disclosure claims benefit of U.S. Provisional Application No. 63/332,673, titled “WAVEFORM SEARCH BY EXAMPLE,” filed on Apr. 19, 2022, the disclosure of which is incorporated herein by reference in its entirety.

### TECHNICAL FIELD

This disclosure relates to test and measurement instruments, and more particularly to techniques for searching for and displaying data of interest in a test and measurement instrument such as an oscilloscope.

### BACKGROUND

Modern oscilloscopes and other test and measurement devices accept one or more signals for testing from a Device Under Test (DUT). Generally, the oscilloscope accepts such input signals at an input port, samples the waveform, converts the samples to a series of digital signals, and stores the sampled input waveform as an acquisition sample waveform. Then tests and measurements are performed by the instrument on the acquisition waveform, which is also called the sample, or sample waveform. And, because the acquisition waveform is stored in an acquisition memory as the sample waveform, tests may be repeatedly performed, or various tests may be formed on the same stored acquisition waveform by the instrument.

Many times the input signals carry information that may repeat over time. In other words, especially when the DUT is a digital device, patterns may be repeated in the input signal. Or defects may appear in the input signal, such as cross-talk from adjacent input signals, which may exhibit as voltage blips or in other measurable ways. Such cross-talk may affect the input signal and degrade its performance. Somewhat frustratingly, defects, such as cross-talk and other defects may appear only irregularly in the input signal. Various triggers and other types of testing techniques may be used to try to isolate defects or locate similar portions of a waveform that repeat. For instance, a certain defect may appear as a small voltage spike a short time after a large voltage signal has passed. In these instances, the user may set a trigger to scan the sample waveform for such conditions. Or the user may wish to isolate instances of the beginning of a memory read within the input signal. But the defects may vary somewhat from defect to defect, or may have other qualities that escape detection using known techniques. And even searching for read starts or other operations that are transmitted within the input signal may be inaccurate when the signals making up the operations vary from one to another due to various factors.

Embodiments according to the disclosure address these and other limitations found in conventional instruments.

### BRIEF DESCRIPTION OF THE DRAWINGS

FIG. 1 illustrates an example output display of a test and measurement instrument including a search by example feature according to embodiments of the disclosure.

FIG. 2 illustrates another example output display of a test and measurement instrument including a search by example feature according to embodiments of the disclosure.

FIG. 3 illustrates yet another example output display of a test and measurement instrument including a search by example feature according to embodiments of the disclosure.

FIG. 4 illustrates a known example correlation algorithm used in embodiments according to the disclosure.

FIG. 5 is a graph illustrating correlation factors generated in embodiments according to the disclosure.

FIG. 6 is an example folded output display of a test and measurement instrument including a search by example feature according to embodiments of the disclosure.

FIG. 7 is an example block diagram illustrating components of a test and measurement instrument on which embodiments according to the disclosure may operate.

### DESCRIPTION

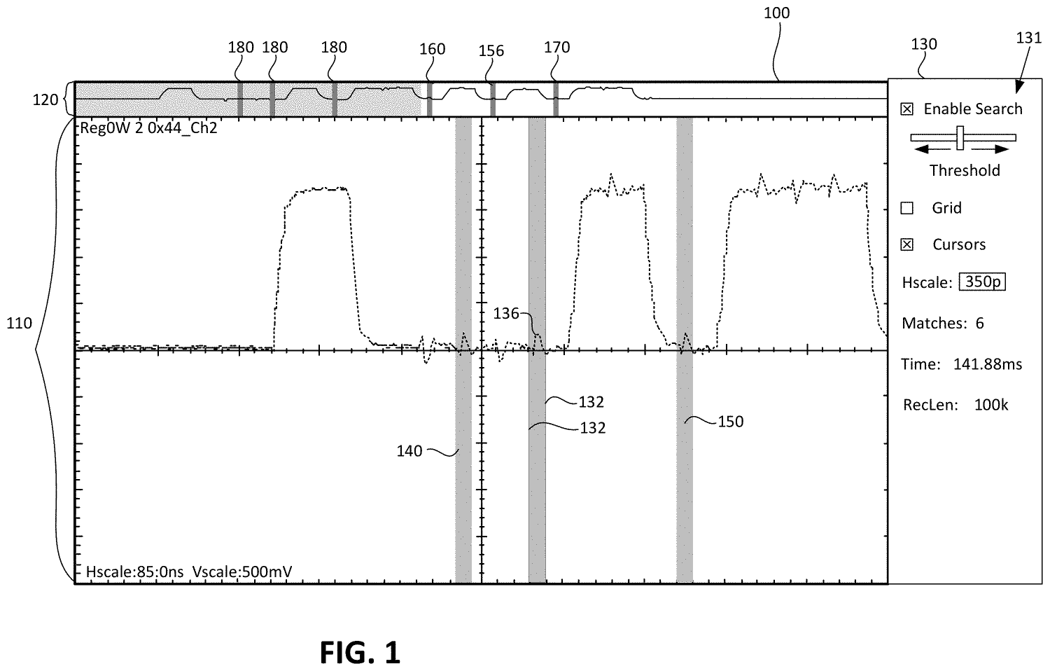

FIG. 1 is an example output display 100 of a test and measurement instrument showing a portion of an acquired input waveform stored as a sample. In this instance the acquired waveform is a Radio Frequency Front End (RFFE) waveform. Embodiments according to the disclosure provide an interface and functionality that allows a user to select a user-definable portion of the waveform. Then the user may control the instrument to search for and locate other instances of similar portions within the stored sample waveform, with the search results highlighted to the user in a format that is easy to visualize the results.

The output display 100 of FIG. 1 includes several components, the appearance or presence of which may be controlled by the user. A main display 110 shows a portion of the sampled waveform to the user. Typically the main display 110 includes a graticule or other indications of measured parameters, which may include voltage, current, or power, for example versus time. Since the sampled waveform may be quite large, generally the main display 110 illustrates only a portion of the entire sampled waveform stored in the instrument at any one time, e.g., a zoomed portion of the waveform. The user may control how much of the sampled waveform is displayed, in a known manner. An overview display 120 of the main display 100 is illustrated adjacent the main display 110. In FIG. 1 the overview display 120 is illustrated above the output display 110, but the relative positions of the main display 110 and overview display 120 may be user controllable. Sometimes the overview display 120 is referred to as the ‘defender’ display, based on its similarity to the popular video game. The overview display 120 shows the entire sampled waveform. The overview display 120 may include an indication or index to the user where the portion of the waveform shown in the main display 110 appears relative to the entire sampled waveform, since the main display generally does not show the entire sampled waveform.

A search tool 131 appears as part of a user interface 130, which may be located adjacent to the output display 100 or in another portion of the display of the test and measurement instrument. The search tool 131 includes tools and functionality that allows the user to identify particular portions of the sampled waveform. To identify these portions, the user first selects the ‘cursors’ box in the user interface 130, which causes a pair of cursors 132 to appear on the main display 110. The horizontal position of the cursors 132 is controlled by the user through a user interface in the main display 110 to identify and select a beginning and ending of a portion of the sampled waveform for searching. The portion of the waveform between the cursors 132 is the portion of the waveform selected for the search, referred to as the search portion 136. The cursors 132 are independently controllable, which means that the portion of the waveform selected for the search can have any width. Also, by expanding or contracting the portion of the waveform shown on the main display 110, the user may select very large portions of the waveform or very small portions of the waveform for searching.

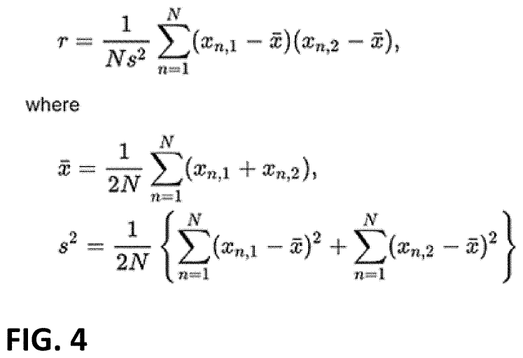

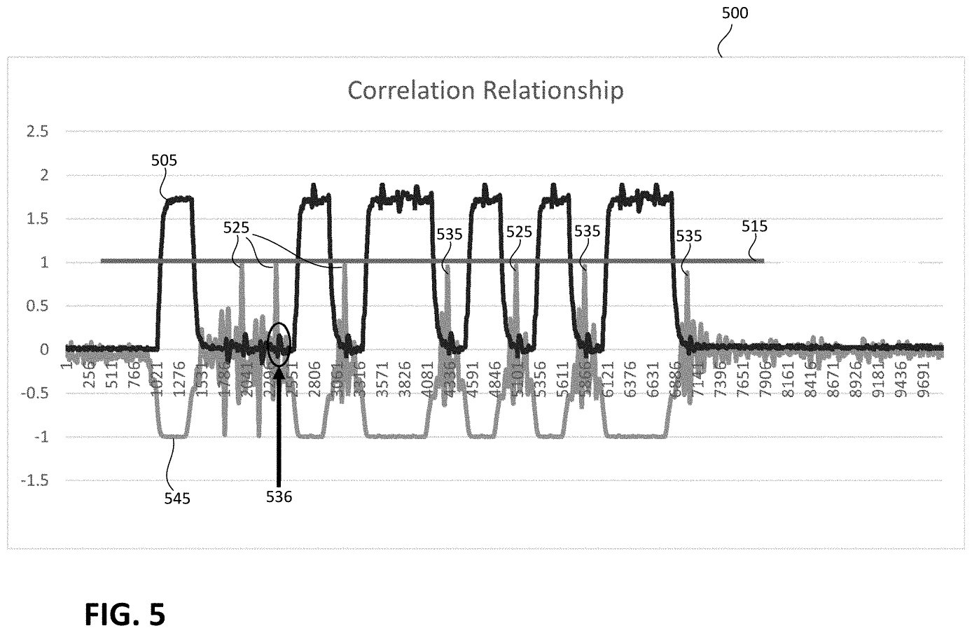

The user initiates the search by first positing the cursors 132 to select the search portion 136, and then selecting the ‘enable search’ box in the search tool 131. When so selected, embodiments according to the disclosure search the entire sampled waveform looking for occurrences in the sampled waveform that match the search portion 136. A detailed description of how the sampled waveform is searched is provided below with reference to FIGS. 4 and 5. A threshold control, which in this embodiment is a slider control, allows the user to specify how close of a match to the search portion 136 portions of the sampled waveform need to be in order to be identified as matches. Moving the slider to the right increases how close portions of the sampled waveform need to be to the search portion 136 to be considered matches. Similarly, moving the slider to the left decreases how close portions of the sampled waveform need to be to be considered matches. The threshold control need not be a slider, and, in fact, need not be graphically illustrated. In other embodiments the user could enter a percentage match using a keyboard. Other forms of a control for receiving an indication of the desired level of match are also possible, such as a controllable mechanical or computer-generated knob in the user interface 130. Once the desired threshold is established by the user, embodiments of the disclosure then visually indicate those portions of the sampled waveform that are considered to be matches to the search portion 136. In FIG. 1, matches 140 and 150 are highlighted on the main display 110 to visually indicate the search results. Note that the portion of the waveform in matches 140 and 150 are generally, but not completely, similar to the search portion 136. Had the user wanted identical or near identical matches, the user would increase the threshold slider, or other control in the search tool 131 to cause the search system to no longer consider matches 140, 150 to be qualified matches. In operation, the instrument generates the matches in real-time or near real-time. In the example in FIG. 1, generating the matches took 141.88 ms, which is displayed in the user interface 130, for a waveform having a record length of 100,000 samples. Thus, the user may control the threshold slider in the search tool 131 and see in real-time or near real-time the matches that are highlighted in the main display 110.

Embodiments of the disclosure additionally visually indicate matched portions of the sampled waveform in the overview display 120. Match 156 on the overview display 120 corresponds to the search portion 136, and matches 160, 170 correspond to matches 140, 150, respectively. Additional matches 180 are not illustrated in the main display 110, because they are out of view, but are still illustrated on the overview display 120. In FIG. 1 these additional matches 180 are indicated with shading or highlighting, but other indications, such as arrows, changing the color, line style, and/or data point markers of the matched portions, or any other type of visual indicators may also indicate matches. Highlighting these additional matches 180 in the overview display 120 shows the user where in the sampled waveform matches appear, even if they are not presently shown on the main display 110. In some embodiments the search portion 136 and its corresponding match 156 appear in a different color than the remaining matches, or otherwise indicate the particular portion of the sampled waveform that is the subject of the search. The total number of matches, in this case 6, is numerically illustrated in the user interface 130. In some embodiments, start and end times of matches may be gathered and stored in a datafile or in list form. In this way the user could use the stored times to locate particular portions of the sample waveform for later analysis.

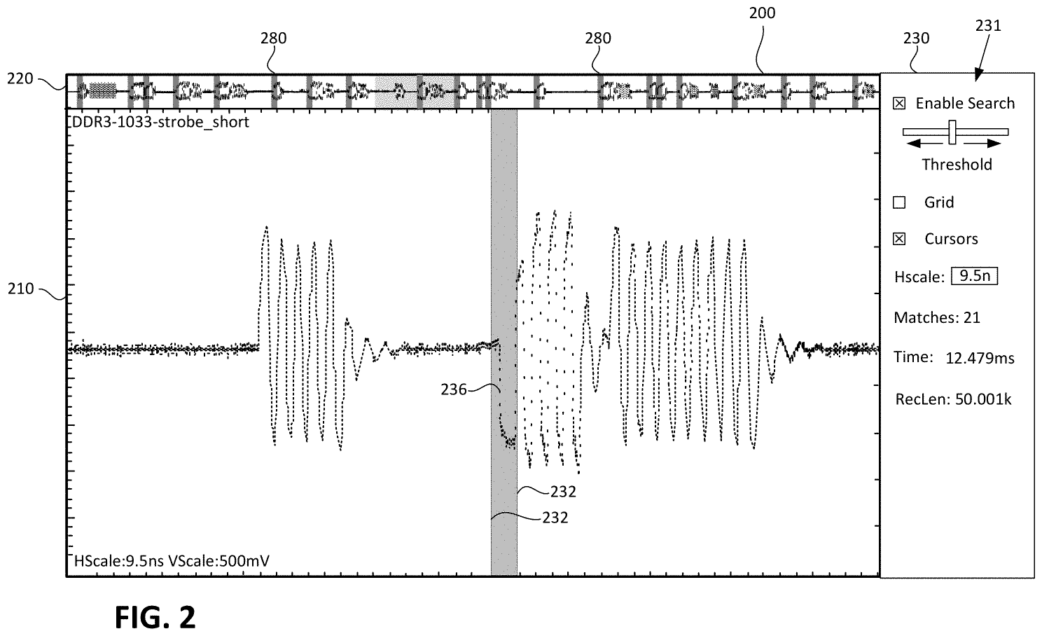

FIG. 2 illustrates another waveform in a display 200. The display 200 includes a main display 210 and overview display 220 that operate similarly to the main display 110 and overview display 120 of FIG. 1. The sample acquisition illustrated in FIG. 2 is a DDR3 (Double Data Rate 3) signal common in some memories, such as SDRAM (Synchronous Dynamic Random-Access Memory). A search portion 236 of the DDR3 waveform selected between cursors 232 identifies a beginning of a memory read in the DDR3 waveform. After the user selects the search portion 236 by manipulating the cursors 232, the search is initiated when the user selects the ‘enable search’ box in the search tool 231 of the user interface 230. In the example illustrated in FIG. 2, the system located 21 matches and indicates the matches as indications 280 in the overview display 220. Not all matches 180 are labeled in FIG. 2 but do appear as shaded portions in the overview display 220. Differently than in FIG. 1, no matches appear in the main display 210, other than the search portion 236 itself. More or fewer matches may be controlled by adjusting the threshold slider 231 in the user interface 230. Controlling the threshold slider allows the user to select only qualified memory reads that appear in the sampled waveform.

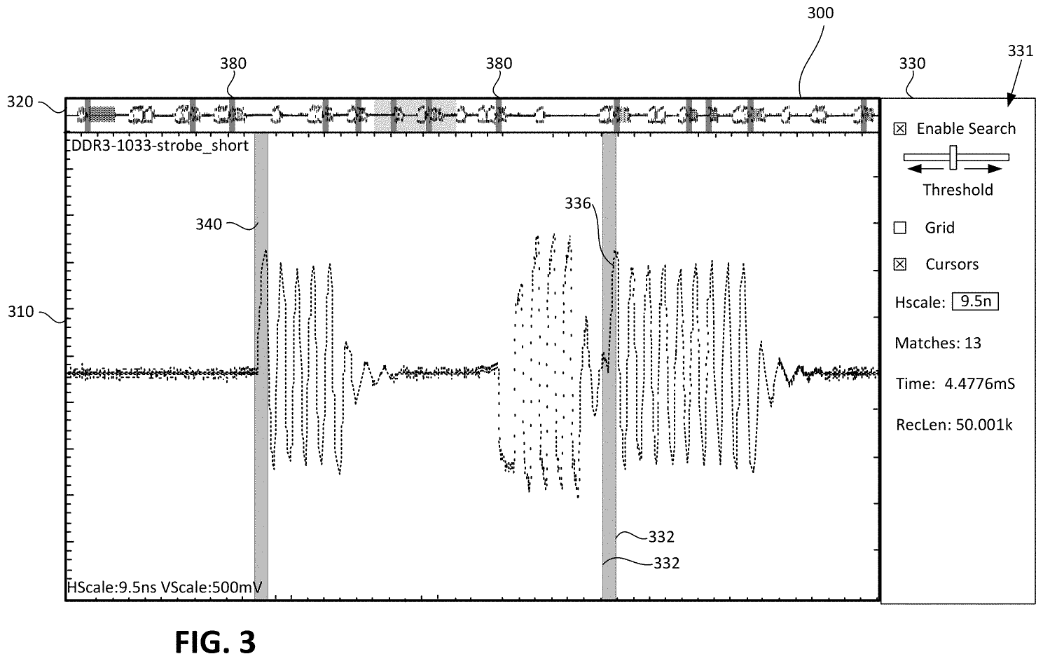

FIG. 3 illustrates another operation on the same DDR3 sampled waveform used in FIG. 2. In the example of FIG. 3, the user has selected a portion of the waveform known to be a read start segment as a search portion 336 in the sampled waveform shown on display 300 by manipulating the cursors 332. After selecting the ‘enable search’ function in the search tool 331 of the user interface 330, the system searches the sampled waveform for matches to the selected read start segment and indicates the total of thirteen matches as 380 in the overview display 320 as well as indicates two matches in the main display 310. Again, not all matches are labeled in FIG. 3, but do appear as shading within the overview display 320. The two matches in the main display 310 of FIG. 3 include the search portion 336, specified by the user, and one additional match 340.

These examples illustrate the power and ease of use embodiments of the disclosure provide to users for identifying portions of the sampled waveform that match selected search portions. In some embodiments, one or more standard search portions, such as pre-defined examples, may be stored in an instrument, and made available to be selected by the user in, for example, the user interface 330. In such an embodiment, the user would select a particular snippet or portion of a waveform desired to be searched. For example, the user could select a read start, write start, beginning or ending of a read, or any other desired portion of any type of waveform. Then, by selecting the ‘enable search’ box in the user interface 330, the system searches the sampled waveform for all of the matches that match the selected search portion. In this embodiment the user interface 330 may store dozens or hundreds of sample portions of waveforms for selection by the user. Further, the user may be able to store his or her own portions of waveforms for later selection. Pre-defined examples may be averages of several snippets or portions of various waveforms to create normalized examples. Additionally, embodiments of the disclosure may automatically scale the pre-defined examples to the displayed scale or sample rate if the examples had a different timescale or sample rate than the present scale and rate illustrated in the main display 310. Such scaling could be performed by interpolation, for instance.

Prior to the technology of this disclosure, finding the beginning of read/write DDR3 packets was a significant effort, involving generating specialized triggers or using other types of waveform matching. However, using the searching mechanisms according to embodiments of the disclosure solves this problem in a way that is accurate, fast, and simple. It's also very flexible, such that any interesting or functionally significant portion of a waveform can be highlighted, and then a test and measurement instrument according to embodiments of the disclosure will automatically search for, find, and visually identify similar portions of the full waveform.

The accuracy of the waveform search function may diminish somewhat as the waveform becomes noisier. However, by adjusting the threshold, described, it is possible to discern matching segments even when there is a significant amount of noise within the sampled waveform.

The search algorithm, according to some embodiments of the disclosure, uses a form of InterClass Correlation (ICC) correlation, an example of which may be represented by the known equations illustrated in FIG. 4. Other, similar algorithms to ICC correlation can be used in alternative embodiments, but ICC correlation is used in preferred embodiments because it has been found to work well with waveform data, such as waveforms acquired from electronic and electro-optical devices under test (DUTs).

An example algorithm that uses ICC to find matches is represented below:

```
Public IResultCollection Correlation(
      INormalizedVector reference,
      INormalizedVector vector,
      double threshold = 0.78)
{
  var rc = new ResultCollection( );
  long count = reference.Count;
  if (count <= 0) return rc;
  double[ ] r1 = reference.ToArray( );
  double[ ] v1 = vector.ToArray( );
  for (int i = 0; i < vector.Count − reference.Count; i++)
  {
      double coeff = ICCCorrelationCoeff(r1, v1, i);
      if (!( (threshold >= 0.0 && coeff >= threshold) | |
        (threshold < 0.0 && coeff <= threshold) ) ) continue;
      rc.Add(new Result
      {
        Begin = vector.Horizontal.IndexToValue(i),
        End = vector.Horizontal.IndexToValue(i + count − 1),
        Focus = vector.Horizontal.IndexToValue(i + count/2),
        Value = coeff
      });
      i += (int) (count − 1);
  }
  rc.Commit( );
  return rc;
}
```

This example algorithm walks a window that is the same width of the search portion (called “reference”) through each point of the input vector where the vector is partitioned into a new vector starting at the index and continuing through the length of the reference. The final result is a correlation value between −1 and 1, where 1 means 100% correlated, and −1 means inverse correlated. 0 means there is no discernable correlation. In addition, if the correlation value for the particular portion of the sample waveform meets or exceeds a threshold, the particular portion of the sample waveform is considered a match to the search portion.

FIG. 5 illustrates the operation of the example algorithm produced above. A sample waveform 505 is the waveform to be searched. A search portion 536 of the sample waveform 505 is indicated with a small oval. The search portion 536 in this example is the same as search portion 136 of FIG. 1. A threshold level 515 is set at or near 1.0, meaning that, in this example, in order to be considered a match to the search portion, a portion of the sample waveform 505 needs to be very close to an exact match to the search portion 536. A correlation value for each window of the sample waveform 505 is generated by the example algorithm, which, as described above, generates a correlation value between the portion of the sample waveform 505 in the present window against the search portion 536. When the search portion 536 is closely correlated with the portion of the sample waveform 505 in the present window, a higher correlation value is generated for that portion of the sample waveform 505. A correlation 545 for each window in the sample waveform is generated. Although the correlation values are not typically graphed or shown to the user, FIG. 5 illustrates the correlation values for explanation. In FIG. 5, note that the correlation values 545 are bound between −1 and +1, as described above.

The correlation value 545 has several peaks, where the correlation value for the particular window is at or near the threshold value 515. Peaks 525 are those that meet or exceed the threshold value 515, while peaks 535 do not. In this example, windows of the sampled waveform that caused the correlation values to exceed the threshold value 515, i.e., those windows that generated correlation peaks 525, are considered matches, and are indicated to the user as described above. Since the correlation values for windows that generated correlation peaks 535 do not meet or exceed the threshold, they would not be identified as matches. As described above, the threshold value 515 is adjustable by the user. So, in the example of FIG. 5, if the threshold value 515 were adjusted to be, for example, 0.90, then all of the windows of the sampled waveform that caused all of the peaks 525 and 535 would be considered matches and shown to the user.

The above example algorithm may be optimized for speed, and, in some embodiments, is optimized for GPU or FPGA acceleration. In one example, the current performance searching for a memory read measured on a laptop computer for a DDR3 sample waveform on a 5M sized record is about 400 mS and found 1898 matching segments. Write segment matching on the same waveform was about 200 mS. The time for performing matches is lower because the write reference segment is about half the size of a read segment, and speed of matching depends on the reference segment size and record length of the vector.

It is possible to achieve similar behavior by using other correlation algorithms or algorithms that are related to correlation. It would also be possible to create a “segment limit mask” and progress that mask through the waveform to find matching regions.

An example use case for applying embodiments of the disclosure includes finding instances of cross-talk aggressors. For this example, two or more channels may be operating on the measurement instrument, with each channel correlated in time. The user selects an artifact of a sample waveform on a first channel that may indicate possible crosstalk effects from an aggressor channel. The search is performed by selecting the artifact as the search portion on a victim channel of interest. After the matches are generated, the user steps through the corresponding matches and visually looks for simultaneous transitions on sample waveforms for other channels. For example, the anomalous peaks in the RFFE signal above are possibly caused by the signal being the victim of crosstalk with a clock signal. Selecting one of the peaks and then comparing the timing of the peaks to waveform behavior on the clock channel can confirm that the waveform artifact is cause by crosstalk.

Another example of embodiments according to the disclosure provides the user a tool to find elements of interest in serial data. As described above, many input signals being tested have repeating features, such as signature rising or falling edges, or artifacts. Selecting one of those features as the search portion allows the user to quickly locate other portions of the sample waveform that include the same features or behaviors. Example features may include a beginning of a packet, end of a packet, and specific bit sequences, etc.

Yet another example includes counting or visualizing repeating anomalies. In this example, the user selects an anomaly of interest to determine if it is a unique occurrence. If the anomaly is unique, no matches would be found in the sampled waveform. If instead the anomaly is recurring, embodiments according to the disclosure will locate and indicate the anomalies as matches. Further, as illustrated in FIGS. 1-3, a match count is provided in the user interface portion. Thus, the number of anomalies matching the selected anomaly in the sampled waveform is tallied and shown to the user. Such a feature may help the user understand the frequency of the occurrences, and possibly a pattern to their location within the sampled waveform.

A further example may include performing independent searches on two channels, simultaneously. Typically the channels would be related in time to one another, but, as described above, embodiments of the disclosure may account for time differences by modifying one of the sampled waveforms to match another, or by automatically including interpolation, or other techniques to time correlate the waveforms during analysis. In this example, a user performs a search on a first channel, by selecting a portion of the first sampled waveform to be searched. Then the user performs a search on a second channel, which typically (but not necessarily) includes a different sampled waveform, such as a second waveform. The user may select the same search portion to be searched in both the first sampled waveform and the second sampled waveform, or the user may select different search portions for each individual waveform. Additionally, different thresholds may be applied to the two different searches. Generally, results matching the individual searches are visually indicated on the output device of each respective waveform display. Further, a second visual indication may appear on a waveform display that indicates where matches occurred on the other waveform. In some embodiments, the results of the two searches may be evaluated using Boolean functions. In other words, it is possible to visually indicate to the user whether searches, for the same time period, occur in both the searches for the first waveform and the second waveform. Yet further, any Boolean function between the search results may be implemented as well, such as OR, AND, and XOR, and in any combination including the NOT function. For example, embodiments of the disclosure may visually indicate on one or both of the waveform displays only those search results that overlapped in time, or were in a controllable threshold of time difference. Still further, these independent searches are not limited to only two channels, but may used with any number of channels that can be independently searched.

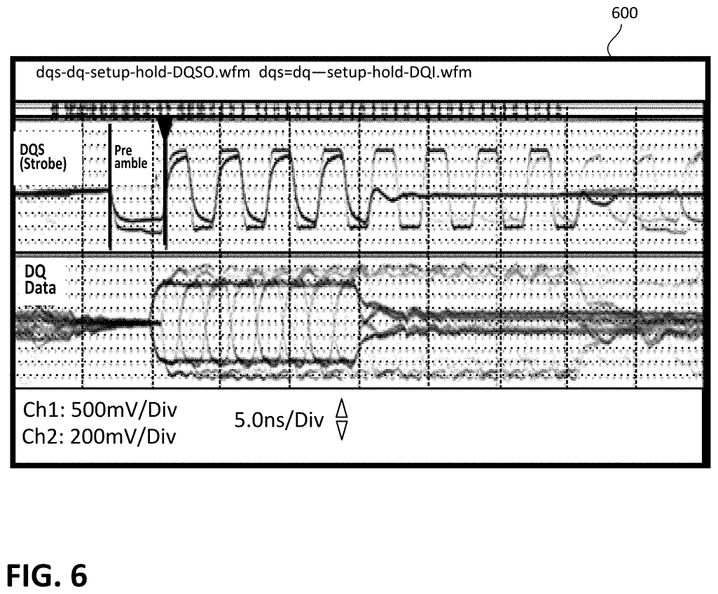

FIG. 6 is an example output display of the test and measurement device that shows how an acquired waveform may be ‘folded’ on to one another and displayed simultaneously. In this example the original acquired waveform is a DDR2 (Dynamic Data Rate 2) signal received from a DUT. Multiple frames or other repeating segments are gathered by the instrument and displayed together in a composite display, such as the display 600. Matches to particular search segments may be used as gates to cause the instrument to reset each segment to time zero, and then show each matched segment simultaneously. In this way the user may view multiple instances of the same or similar waveform behavior on the display. In the example of FIG. 6, a relationship between reads and writes is observed when both are presented simultaneously on a folded display. In the illustrated example, a phase difference in the data signal and an amplitude difference in the DQS strobe signal may be observed by viewing the display 600. This type of folded view such as the display 600 is very useful for seeing relationships between various signals.

Various embodiments of the disclosure may also include an ability for the user to view properties of waveforms across two or more channels, each accepting a different waveform looking for matches. For example, the two or more channels may be separate channels of a data bus. Each acquired sample for each channel may have individually selectable threshold levels. In some embodiments, to be considered a match, all included waveforms for all selected channels would have to meet their respective thresholds.

Embodiments of the disclosure may also be used to combine one or more reference searches, such as identifying the beginning of DDR2 read followed by an end of packet indication. The result could be labeled as “read packet”.

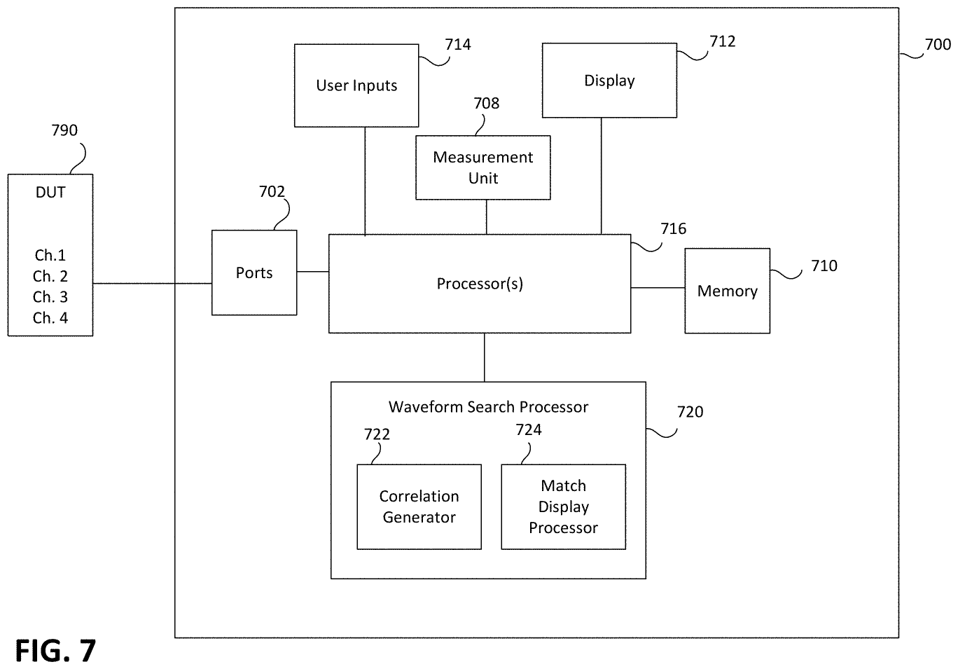

Embodiments of the disclosure operate on particular hardware and/or software to implement the above-described operations. FIG. 7 is a block diagram of an example test and measurement instrument 700, such as an oscilloscope or spectrum analyzer for implementing embodiments of the disclosure disclosed herein. The test and measurement instrument 700 includes one or more ports 702, which may be any signaling medium. The ports 702 may include receivers, transmitters, and/or transceivers. Each port 702 is a channel of the test and measurement instrument 700. The ports 702 are coupled with one or more processors 716 to process the signals and/or waveforms received at the ports 702 from one or more devices under test (DUTs) 790. In some embodiments the ports accept multiple signals from the DUT 790, or from one or more DUTs. Although a four-signal DUT 790 is illustrated in FIG. 7, the test and measurement instrument 700 may accept any number of input signals up to the number of ports 702. Also, although only one processor 716 is shown in FIG. 7 for ease of illustration, as will be understood by one skilled in the art, multiple processors 716 of varying types may be used in combination in the instrument 700, rather than a single processor 716.

The ports 702 can also be connected to a measurement unit 708 in the test instrument 700. The measurement unit 708 can include any component capable of measuring aspects (e.g., voltage, amperage, amplitude, power, energy, etc.) of a signal received via ports 702. The test and measurement instrument 700 may include additional hardware and/or processors, such as conditioning circuits, analog to digital converters, and/or other circuitry to convert a received signal to a waveform for further analysis. The resulting waveform can then be stored in a memory 710, as well as displayed on a display 712.

The one or more processors 716 may be configured to execute instructions from the memory 710 and may perform any methods and/or associated steps indicated by such instructions, such as displaying and modifying the input signals received by the instrument. The memory 710 may be implemented as processor cache, random access memory (RAM), read only memory (ROM), solid state memory, hard disk drive(s), or any other memory type. The memory 710 acts as a medium for storing data, such as acquired sample waveforms, computer program products, and other instructions.

User inputs 714 are coupled to the processor 716. User inputs 714 may include a keyboard, mouse, touchscreen, and/or any other controls employable by a user to set up and control the instrument 700. User inputs 714 may include a graphical user interface or text/character interface operated in conjunction with the display 712. The user inputs 714 may receive remote commands or commands in programmatic form. The user interfaces 130, 230, 330 described above may be a part of the user inputs 714. User inputs 714 may further include programmatic inputs from the user on the instrument 700, or from a remote device. The display 712 may be a digital screen, a cathode ray tube based display, or any other monitor to display waveforms, measurements, and other data to a user. While the components of test instrument 700 are depicted as being integrated within test and measurement instrument 700, it will be appreciated by a person of ordinary skill in the art that any of these components can be external to test instrument 700 and can be coupled to test instrument 700 in any conventional manner (e.g., wired and/or wireless communication media and/or mechanisms). For example, in some embodiments, the display 712 may be remote from the test and measurement instrument 700, or the instrument may be configured to send output to a remote device in addition to displaying it on the instrument 700. In further embodiments, output from the measurement instrument 700 may be sent to or stored in remote devices, such as cloud devices, that are accessible from other machines coupled to the cloud devices.

The instrument 700 may include a waveform search processor 720, which may be a separate processor from the one or more processors 716 described above, or the functions of the waveform search processor 720 may be integrated into the one or more processors 716. Additionally, the waveform search processor 720 may include separate memory, use the memory 710 described above, or any other memory accessible by the instrument 700. The waveform search processor 720 may include specialized processors to implement the functions described above. For example, the waveform search processor 720 may include a correlation generator 722 used to generate the correlations for waveform searching using procedures and operations described above to implement waveform search generation. A match display processor 724 may generate the matches based on the generated correlations and show them to the user on the display 712. The match display processor 724 may control updating the match display in real time or near-real time as elements of the display are manipulated by the user, such as the threshold control slider. Any or all of the components of the waveform search processor 720, including the correlation generator 722 and match display processor 724 may be embodied in one or more separate processors, and the separate functionality described herein may be implemented as specific pre-programmed operations of a special purpose or general purpose processor. Further, as stated above, any or all of the components or functionality of the waveform search processor 720 may be integrated into the one or more processors 716 that operate the instrument 700.

In some embodiments the waveform search processor 720 may be on a separate device from an instrument that acquired the input signal for testing. In such an embodiment the separate device may retrieve the acquired waveform from a remote device, or retrieve it from a remote storage device, and perform the searching functions described above on the separate device. Then the results may be displayed on the separate device, or, as described above, may be exported from the separate device to be shown on a different device. In yet other embodiments, the separate device may locally store the search results and make them available for use by a user of a remote device.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement instrument, including an input for accepting an input signal from a Device Under Test (DUT), acquisition memory for storing a sampled waveform derived from the input signal, an output display, and one or more processors configured to accept a portion of the sampled waveform as a search portion, search the sampled waveform for portions similar to the search portion, and visually indicate, on the output display, those portions of the sampled waveform that are similar to the search portion as matched portions.

Example 2 is a test and measurement according to Example 1, in which a degree of similarity to the search portion that the portions of the sampled waveform exceed to be considered matched portions is user controllable.

Example 3 is a test and measurement device according to any of the preceding Examples, in which the one or more processors are configured to accept a portion of the waveform between two user-controllable cursors as the search portion.

Example 4 is a test and measurement device according to any of the preceding Examples, in which the one or more processors configured to visually indicate portions of the sampled waveform as matched portions are configured to highlight the matched portions on the output display.

Example 5 is a test and measurement device according to any of the preceding Examples, in which the search portion is selected from a list of stored search portions.

Example 6 is a test and measurement device according to any of the preceding Examples, in which the one or more processors configured to search the sampled waveform for portions similar to the search portion are configured to generate a correlation value for one or more portions of the sampled waveform.

Example 7 is a test and measurement device according to Example 6, in which the one or more processors are configured to visually indicate a matched portion when the correlation value for a particular one of the one or more portions of the sampled waveform are correlated to the search portion above a threshold correlation value.

Example 8 is a test and measurement device according to any of the preceding Examples, in which the one or more processors configured to visually indicate portions of the sampled waveform as matched portions are configured to simultaneously visually indicate portions of the sampled waveform in a main display as well as in an overview display that includes the entire sampled waveform.

Example 9 is a test and measurement device according to any of the preceding Examples, in which the one or more processors are configured to search the sample waveform for portions similar to the search portion only after being requested to perform the search by a user.

Example 10 is a test and measurement device according to any of the preceding Examples, further comprising a second input for accepting a second input signal, in which the acquisition memory is configured to store a second sampled waveform derived from the second input signal, and in which the one or more processors are configured to visually indicate matched portions on a display showing the second sampled waveform.

Example 11 is a test and measurement device according to Example 10, in which the one or more processors are configured to accept a portion of the second sampled waveform as a second search portion, search the second sampled waveform for portions similar to the second search portion, and visually indicate, on the output display, those portions of the sampled waveform and/or portions of the second sampled waveform that are similar to the second search portion as second matched portions.

Example 12 is a test and measurement device according to Example 11, in which the one or more processors are configured to visually indicate matches only when portions of the sampled waveform are similar to the search portion and portions of the second sampled waveform are similar to the second search portion.

Example 13 is a method of operation of a test and measurement instrument, including searching a sampled waveform stored on the test and measurement instrument for portions similar to a selected portion of the sampled waveform, and visually indicating, on an output display, portions of the sampled waveform that are similar to the selected portion of the sampled waveform as matched portions.

Example 14 is a method according Example 13, further including accepting an input signal from a Device Under Test (DUT), generating the sampled waveform derived from the input signal, and storing the sampled waveform on the test and measurement instrument.

Example 15 is a method according to any of the preceding Example methods, in which searching the sampled waveform comprises generating a correlation value for portions of the sampled waveform based on their correlation to the selected portion of the sampled waveform.

Example 16 is a method according to any of the preceding Example methods, in which visually indicating portions of the sampled waveform that are similar to the selected portion of the sampled waveform comprises visually indicating only those portions of the sampled waveform that include a correlation value that exceeds a threshold correlation value.

Example 17 is a non-transitory computer-readable storage medium storing one or more instructions, which, when executed by one or more processors of a computing device, cause the computing device to search a sampled waveform accessible by the computing device for portions similar to a selected portion of the sampled waveform, and visually indicate, on an output display, portions of the sampled waveform that are similar to the selected portion of the sampled waveform as matched portions.

Example 18 is the non-transitory computer-readable storage medium according to Example 17, wherein execution of the one or more instructions further causes the computing device to accept an input signal from a Device Under Test (DUT), generate a sample waveform derived from the input signal, and store the sample waveform on the computing device.

Example 19 is the non-transitory computer-readable storage medium according to Example 18, wherein execution of the one or more instructions further causes the computing device to generate a correlation value for portions of the sampled waveform based on their correlation to the selected portion of the sampled waveform.

Example 20 is the non-transitory computer-readable storage medium according to any of the preceding Examples 17-19, wherein execution of the one or more instructions further causes the computing device to visually indicate only those portions of the sampled waveform that include a correlation value that exceeds a threshold correlation value.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A test and measurement instrument, comprising:
an input for accepting an input signal from a Device Under Test (DUT);
acquisition memory for storing a sampled waveform derived from the input signal;
an output display; and
one or more processors configured to:
accept a portion of the sampled waveform as a search portion,
search the sampled waveform for portions similar to the search portion, and
visually indicate, on the output display, those portions of the sampled waveform that are similar to the search portion as matched portions.

2. The test and measurement instrument according to claim 1, in which a degree of similarity to the search portion that the portions of the sampled waveform exceed to be considered matched portions is user controllable.

3. The test and measurement instrument according to claim 1, in which the one or more processors are configured to accept a portion of the waveform between two user-controllable cursors as the search portion.

4. The test and measurement instrument according to claim 1, in which the one or more processors configured to visually indicate portions of the sampled waveform as matched portions are configured to highlight the matched portions on the output display.

5. The test and measurement instrument according to claim 1, in which the search portion is selected from a list of stored search portions.

6. The test and measurement instrument according to claim 1, in which the one or more processors configured to search the sampled waveform for portions similar to the search portion are configured to generate a correlation value for one or more portions of the sampled waveform.

7. The test and measurement instrument according to claim 6, in which the one or more processors are configured to visually indicate a matched portion when the correlation value for a particular one of the one or more portions of the sampled waveform are correlated to the search portion above a threshold correlation value.

8. The test and measurement instrument according to claim 1, in which the one or more processors configured to visually indicate portions of the sampled waveform as matched portions are configured to simultaneously visually indicate portions of the sampled waveform in a main display as well as in an overview display that includes the entire sampled waveform.

9. The test and measurement instrument according to claim 1, in which the one or more processors are configured to search the sample waveform for portions similar to the search portion only after being requested to perform the search by a user.

10. The test and measurement instrument according to claim 1, further comprising a second input for accepting a second input signal, in which the acquisition memory is configured to store a second sampled waveform derived from the second input signal, and in which the one or more processors are configured to visually indicate matched portions on a display showing the second sampled waveform.

11. The test and measurement instrument according to claim 10, in which the one or more processors are configured to:
accept a portion of the second sampled waveform as a second search portion,
search the second sampled waveform for portions similar to the second search portion, and
visually indicate, on the output display, those portions of the sampled waveform and/or portions of the second sampled waveform that are similar to the second search portion as second matched portions.

12. The test and measurement instrument according to claim 11, in which the one or more processors are configured to visually indicate matches only when portions of the sampled waveform are similar to the search portion and portions of the second sampled waveform are similar to the second search portion.

13. A method of operation of a test and measurement instrument, comprising:
searching a sampled waveform stored on the test and measurement instrument for portions similar to a selected portion of the sampled waveform; and
visually indicating, on an output display, portions of the sampled waveform that are similar to the selected portion of the sampled waveform as matched portions.

14. The method according to claim 13, further comprising:
accepting an input signal from a Device Under Test (DUT);
generating the sampled waveform derived from the input signal; and
storing the sampled waveform on the test and measurement instrument.

15. The method according to claim 13, in which searching the sampled waveform comprises generating a correlation value for portions of the sampled waveform based on their correlation to the selected portion of the sampled waveform.

16. The method according to claim 13, in which visually indicating portions of the sampled waveform that are similar to the selected portion of the sampled waveform comprises visually indicating only those portions of the sampled waveform that include a correlation value that exceeds a threshold correlation value.

17. A non-transitory computer-readable storage medium storing one or more instructions, which, when executed by one or more processors of a computing device, cause the computing device to:
search a sampled waveform accessible by the computing device for portions similar to a selected portion of the sampled waveform; and
visually indicate, on an output display, portions of the sampled waveform that are similar to the selected portion of the sampled waveform as matched portions.

18. The non-transitory computer-readable storage medium according to claim 17, wherein execution of the one or more instructions further causes the computing device to:
accept an input signal from a Device Under Test (DUT);
generate a sample waveform derived from the input signal; and
store the sample waveform on the computing device.

19. The non-transitory computer-readable storage medium according to claim 18, wherein execution of the one or more instructions further causes the computing device to:
generate a correlation value for portions of the sampled waveform based on their correlation to the selected portion of the sampled waveform.

20. The non-transitory computer-readable storage medium according to claim 17, wherein execution of the one or more instructions further causes the computing device to:
visually indicate only those portions of the sampled waveform that include a correlation value that exceeds a threshold correlation value.
